(19) United States
(12) Patent Application Publication
(10) Pub. No.: US 2020/0295103 A1
(43) Pub. Date: Sep. 17, 2020

(54) PIXEL DEFINING STRUCTURE AND FABRICATING METHOD THEREOF, DISPLAY PANEL AND DISPLAY DEVICE

(71) Applicants: Fuzhou BOE Optoelectronics Technology Co., Ltd., Fuqing (CN); BOE TECHNOLOGY GROUP CO., LTD., Beijing (CN)

(72) Inventors: Zhenyou Zou, Beijing (CN); Liangliang Li, Beijing (CN); Rong Wu, Beijing (CN); Kaibin Kong, Beijing (CN); Yazhou Huo, Beijing (CN); Wenxing Xi, Beijing (CN)

(21) Appl. No.: 16/561,781

(22) Filed: Sep. 5, 2019

(30) Foreign Application Priority Data
Mar. 14, 2019 (CN) 201910194843.2

(51) Int. Cl. H01L 27/32; H01L 51/00; H01L 51/56

(52) U.S. Cl. CPC H01L 27/3246; H01L 51/56; H01L 51/0005; H01L 51/0018

(57) ABSTRACT

A pixel defining structure includes a first pixel defining portion formed on a base substrate, the first pixel defining portion having a pixel opening, a bump pattern formed on the base substrate and located in the pixel opening, a gap being formed between the bump pattern and the first pixel defining portion, and a second pixel defining portion formed on a surface of the first pixel defining portion away from the base substrate.

### CROSS REFERENCE

This application is based upon and claims priority to Chinese Patent Application No. 201910194843.2, filed on Mar. 14, 2019, the entire contents thereof are incorporated herein by reference.

### TECHNICAL FIELD

The present disclosure relates to the technical field of display, in particular to a pixel defining structure, a fabricating method of the pixel defining structure, a display panel and a display device.

### BACKGROUND

Currently, an organic light emitting functional layer in an Organic Light Emitting Diode (OLED) device is mainly formed by an ink jet printing process, that is, an organic light emitting solution can be precisely filled into a pixel region defined by a pixel defining structure by an ink jet printer to form the organic light emitting functional layer. However, the film thickness uniformity of the organic light emitting functional layer formed by this method is poor and thus a coffee ring effect is easily generated, so that the light emitting effect is easily affected.

It should be noted that the information disclosed in the background section above is only intended to enhance understanding of the background of the present disclosure, and thus may include information that does not constitute prior art known to those of ordinary skill in the art.

### SUMMARY

A first aspect of the present disclosure provides a pixel defining structure. The pixel defining structure includes a first pixel defining portion formed on a base substrate. The first pixel defining portion has a pixel opening. The pixel defining structure includes a bump pattern formed on the base substrate and located in the pixel opening. A gap is formed between the bump pattern and the first pixel defining portion. The pixel defining structure includes a second pixel defining portion formed on a surface of the first pixel defining portion away from the base substrate.

In an example arrangement of the present disclosure, the bump pattern is mirror-symmetrical with respect to a center line of the pixel opening.

In an example arrangement of the present disclosure, the bump pattern includes a plurality of bumps spaced apart from one another, and a distance between adjacent bumps gradually increases along a direction from a center of the bump pattern to an edge of the bump pattern.

In an example arrangement of the present disclosure, a thickness of the bump is less than a thickness of the first pixel defining portion.

In an example arrangement of the present disclosure, the bump has a thickness of 0.5 μm to 1.0 μm, and the first pixel defining portion has a thickness of 1.0 μm to 2.0 μm.

In an example arrangement of the present disclosure, the first pixel defining portion and the bump pattern are made of lyophilic material, and the second pixel defining portion is made of lyophobic material.

In an example arrangement of the present disclosure, an orthographic projection of a surface of the first pixel defining portion away from the base substrate on the base substrate is within an orthographic projection of a surface of the first pixel defining portion adjacent to the base substrate on the base substrate.

In an example arrangement of the present disclosure, an orthographic projection of a surface of the second pixel defining portion away from the base substrate on the base substrate is within an orthographic projection of a surface of the second pixel defining portion adjacent to the base substrate on the base substrate.

In an example arrangement of the present disclosure, an orthographic projection area of a surface of the second pixel defining portion adjacent to the base substrate on the base substrate is equal to an orthographic projection area of a surface of the first pixel defining portion away from the base substrate on the base substrate.

A second aspect of the present disclosure provides a fabricating method of a pixel defining structure. The method includes providing a base substrate. The method includes forming a first pixel defining film on the base substrate. The first pixel defining film has at least one pixel region, and the pixel region comprises a first portion and a second portion surrounding the first portion. The method includes performing a first patterning process on the first portion to form a bump pattern. The method includes performing a second patterning process on the second portion to form a first pixel defining portion having a pixel opening. The bump pattern is disposed within the pixel opening, and a gap is formed between the first pixel defining portion and the bump pattern. The method includes forming a second pixel defining portion on a surface of the first pixel defining portion away from the base substrate so as to form a pixel defining structure.

In an example arrangement of the present disclosure, performing the first patterning process on the first portion to form the bump pattern includes: forming a photoresist layer on the first pixel defining film; exposing and developing the photoresist layer to form a photoresist pattern covering the first portion; performing a dry etching process on the first portion by taking the photoresist pattern as a mask to form the bump pattern; and removing the photoresist pattern.

In one example arrangement of the present disclosure, the first pixel defining film is made by means of photo-etching an organic material. Performing the first patterning process on the first portion to form the bump pattern includes exposing and developing the first portion to form the bump pattern.

In one example arrangement of the present disclosure, the first pixel defining portion is made of lyophilic material, and the second pixel defining portion is made of lyophobic material. After performing the second patterning process on the second portion to form the first pixel defining portion having the pixel opening, and before forming the second pixel defining portion on the surface of the first pixel defining portion away from the base substrate, the fabricating method further includes: improving the surface of the first pixel defining portion away from the base substrate so as to enable the surface of the first pixel defining portion away from the base substrate to be compatible with the second pixel defining portion.

A third aspect of the present disclosure provides a display panel. The display panel includes a base substrate. The display panel includes a pixel defining structure formed on the base substrate. The pixel defining structure is any one of the pixel defining structures described above. The display panel includes an organic light emitting functional layer formed in the pixel opening defined by the pixel defining structure.

A fourth aspect of the present disclosure provides a display device including the display panel described above.

It should be understood that the above general description and the following detailed description are intended to be illustrative and not restrictive of the present disclosure.

### BRIEF DESCRIPTION OF THE DRAWINGS

The accompanying drawings are incorporated in and constitute part of the specification, show the arrangements of the present disclosure and are intended to explain the principle of the present disclosure together with the description. It is apparent that the accompanying drawings in the following description are only some of the arrangements of the present disclosure, and other drawings may be obtained from these accompanying drawings by those skilled in the art without any creative work.

FIG. 1 shows a schematic cross-sectional view of a pixel defining structure according to an arrangement of the present disclosure.

FIG. 2 shows a schematic plan view of a pixel defining structure according to an arrangement of the present disclosure.

FIG. 3 shows a flowchart of a fabricating method of a pixel defining structure according to an arrangement of the present disclosure.

FIG. 4 shows a schematic view after completion of S302.

FIG. 5 shows a schematic view after completion of S306.

FIG. 6 shows a schematic view after completion of S3080.

FIG. 7 shows a schematic view after completion of S3082.

FIG. 8 shows a schematic cross-sectional view of a display panel according to an arrangement of the present disclosure.

FIG. 9 shows a flowchart of a fabricating method of a display panel according to an arrangement of the present disclosure.

### DETAILED DESCRIPTION

Example arrangements will now be described more fully with reference to the accompanying drawings. However, the example arrangements can be embodied in a variety of forms, and should not be construed as being limited to the arrangements set forth herein; rather, these arrangements are provided so that this disclosure will be thorough and complete, and the concepts of the example arrangements will be fully given to those skilled in the art. The same reference numerals in the drawings denote the same or similar structures, and thus their detailed descriptions will be omitted.

Although the relative terms such as “on”, “below”, “upper” and “lower” are used in the specification to describe the relative relationship of one component to another component, these terms are used in this specification for convenience only, for example, a direction in the example according to the accompanying drawings. It should be understood that if the device is turned upside down, the “upper” component described above will become a “lower” component. When a structure is “on” another structure, it is possible that the structure is integrally formed on another structure, or that the structure is “directly” disposed on another structure, or that the structure is “indirectly” disposed on the other structure through other structures.

The terms such as “a”, “an”, “the” and “said” are used to indicate the presence of one or more elements/components. The terms “comprise”, “include”, “have”, “contain” and their variants are used to be open-type and are meant to include additional elements/components, etc., in addition to the listed elements/components/etc.; the terms “first”, “second”, etc. are used only as marks, rather than limitation for the number of objects.

Compared with the traditional Liquid Crystal Display (LCD) technology, the OLED display technology has the advantages of self-luminescence, fast response time, high brightness, wide viewing angle, bright color and the like, and is a strong competitor of the next generation display technology.

The OLED device mainly includes an organic light emitting functional layer, an anode electrode layer and a cathode electrode layer. The organic light emitting functional layer is a key material of the OLED device. At present, the forming method of the organic light emitting functional layer may include a vacuum evaporation method, a screen printing method, an ink jet printing method and the like. The vacuum evaporation method is suitable for forming the film of the organic small-molecule light emitting material, which can be a substantially uniform film. However, the equipment investment cost for forming the film is large, the material utilization rate is low, and the alignment precision is low when the film is used for large-size products; while the ink jet printing method and the screen printing method are suitable for film formation of high-molecular polymers and soluble small molecules, with low equipment cost and outstanding large-scale and large-size production.

Taking an ink jet printing method as an example, when an organic light emitting functional layer is manufactured by using the ink jet printing method, a pixel defining structure is required to be formed on a base substrate in advance, and then an organic light emitting solution is accurately filled into a pixel region defined by the pixel defining structure through an ink jet printer to form the organic light emitting functional layer, however, under the action of liquid surface tension, most organic light emitting solution molecules gather towards the middle, so that the formed organic light emitting functional layer presents a situation that it is thick in the middle and thin in the edge, i.e., the organic light emitting functional layer formed by this method has poor film thickness uniformity and is easy to have a coffee ring effect, so that the light emitting effect is easily influenced.

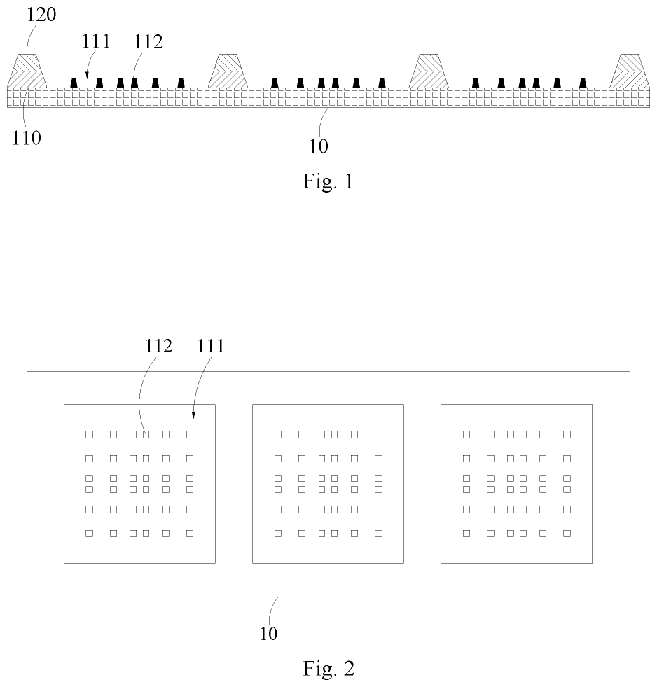

In order to solve the above technical problems, an arrangement of the present disclosure provides a pixel defining structure. The pixel defining structure may be applied to an OLED display panel, but is not limited thereto, and may also be applied to a Quantum Dot Light Emitting Diodes (QLED) display panel. As shown in FIGS. 1 and 2, the pixel defining structure may include a first pixel defining portion 110, a bump pattern, and a second pixel defining portion 120.

Specifically, the first pixel defining portion 110 is formed on the base substrate 10, and the first pixel defining portion 110 has a pixel opening 111. The organic light emitting solution may be filled into the pixel opening 111 to form the organic light emitting functional layer 14, as shown in FIG. 8. Alternatively, an orthographic projection of a surface of the first pixel defining portion 110 away from the base substrate 10 on the base substrate 10 may be within an orthographic projection of a surface of the first pixel defining portion 110 adjacent to the base substrate 10 on the base substrate 10.

The bump pattern is formed on the base substrate 10 and located in the pixel opening 111, i.e., the first pixel defining portion 110 may surround the bump pattern, and a gap is formed between the bump pattern and the first pixel defining portion 110. The bump pattern is arranged in the pixel opening 111 of the first pixel defining portion 110, so that a surface tension of the organic light emitting solution filled in the pixel opening 111 can be damaged, and the situation that the organic light emitting solution gathers towards the middle under the action of the surface tension of liquid can be relieved. That is, the amount of the organic light emitting solution flowing towards the edge (the position where the first pixel defining portion 110 is located) in the pixel opening 111 may be increased under the action of the bump pattern, so that the situation that the formed organic light emitting functional layer 14 is thick in the middle and thin in the edge can be relieved. Thus, the film thickness uniformity of the organic light emitting functional layer 14 in the pixel opening 111 is improved, the situation that the coffee ring effect occurs is relieved, and thus the light emitting effect is improved.

It should be noted that the bump pattern and the first pixel defining portion 110 may be formed in the same layer, and the bump pattern and the first pixel defining portion 110 may be made of the same material. For example, the bump pattern and the first pixel defining portion 110 may be made of lyophilic material, and the lyophilic material has an attraction property to the organic light emitting solution, so as to ensure that molecules of the organic light emitting solution climb over the first pixel defining portion 110 and the bump pattern, thus ensuring a film formation uniformity in the pixel opening 111. The lyophilic material may be silicon dioxide or silicon nitride, but not limited thereto.

Alternatively, the bump pattern in the present arrangement may be mirror-symmetrical with respect to the center line of the pixel opening 111, so as to further improve the film thickness uniformity of the organic light emitting functional layer 14 in the pixel opening 111.

As shown in FIGS. 1 and 2, the bump pattern may include a plurality of bumps 112 spaced apart, and then a distance between adjacent bumps 112 gradually increases from the center of the bump pattern to the edge of the bump pattern, so that the surface tension of the organic light emitting solution filled in the pixel opening 111 can be damaged to a greater extent, thus further improving the film thickness uniformity of the organic light emitting functional layer 14 in the pixel opening 111, alleviating the occurrence of the coffee ring effect, and further improving the light emitting effect.

Further, the thickness of each bump 112 in the bump pattern may be smaller than the thickness of the first pixel defining portion 110, so as to ensure the integrity of the organic light emitting functional layer 14 in the pixel opening 111, and at the same time, avoid the situation that the thickness of the organic light emitting functional layer 14 is higher than the thickness of the first pixel defining portion 110. Thus, the film thickness uniformity of the organic light emitting functional layer 14 is ensured.

For example, the thickness of the bump 112 may be 0.5 μm to 1.0 μm, and the thickness of the first pixel defining portion 110 may be 1.0 μm to 2.0 μm, so that, on one hand, the situation that the surface tension of the organic light emitting solution cannot be damaged by the bump 112 due to the too small thickness of the bump 112 can be avoided, thus ensuring the film thickness uniformity of the organic light emitting functional layer 14, and further reducing the processing difficulty of the bump 112; on the other hand, the situation that the normal light emission of the organic light emitting functional layer 14 is affected due to the excessive thickness of the bump 112 can be avoided.

Note that the thickness value of the bump 112 and the thickness value of the first pixel defining portion 110 are not limited to the above range, and may be other values as required.

As shown in FIG. 1, the second pixel defining portion 120 is formed on the surface of the first pixel defining portion 110 away from the base substrate 10. The second pixel defining portion 120 is used to ensure the height of the whole pixel defining structure so as to avoid mixing of organic light emitting solutions in the adjacent pixel openings 111. Alternatively, an orthographic projection of the surface of the second pixel defining portion 120 away from the base substrate 10 on the base substrate 10 may be within an orthographic projection of the surface of the second pixel defining portion 120 adjacent to the base substrate 10 on the base substrate 10. In addition, an orthographic area of the surface of the second pixel defining portion 120 adjacent to the base substrate 10 on the base substrate 10 may be equal to an orthographic area of the surface of the first pixel defining portion 110 away from the base substrate 10 on the base substrate 10.

For example, the second pixel defining portion 120 may be made of lyophobic material, and the lyophobic material has repulsion to the organic light emitting solution, and the climbing height of the solution on the pixel defining structure can be controlled by the repulsion effect of the lyophobic material, so as to further avoid mixing of the organic light emitting solutions in the adjacent pixel openings 111. In addition, the climbing amount of the organic light emitting solution in different pixel openings 111 may be made to be as same as possible by using the repulsion effect of the lyophobic material, and the film formation uniformity of the solution in the pixel openings 111 is effectively improved. The lyophobic material may be any one of fluorinated polyimide, fluorinated polymethyl methacrylate and polysiloxane.

It should be understood that the pixel defining structure in the present arrangement may include a plurality of pixel regions, and each pixel region may include the above-mentioned first pixel defining portion 110, the bump pattern, and the second pixel defining portion 120. Adjacent pixel regions may share a part of the first pixel defining portion 110, and an organic light emitting functional layer 14 may be formed in the pixel opening 111 defined by the first pixel defining portion 110 in each pixel region, and colors of the organic light emitting functional layer 14 in the pixel opening 111 defined by the first pixel defining portion 110 in pixel regions may be the same or different. In this arrangement, the organic light emitting functional layer 14 in the pixel opening 111 may be a red organic light emitting functional layer, a green organic light emitting functional layer, or a blue organic light emitting functional layer. The red organic light emitting functional layer is configured to emit red light, the green organic light emitting functional layer is configured to emit green light, and the blue organic light emitting functional layer is configured to emit blue light, but not limited thereto. The organic light emitting functional layer 14 may also be in other colors.

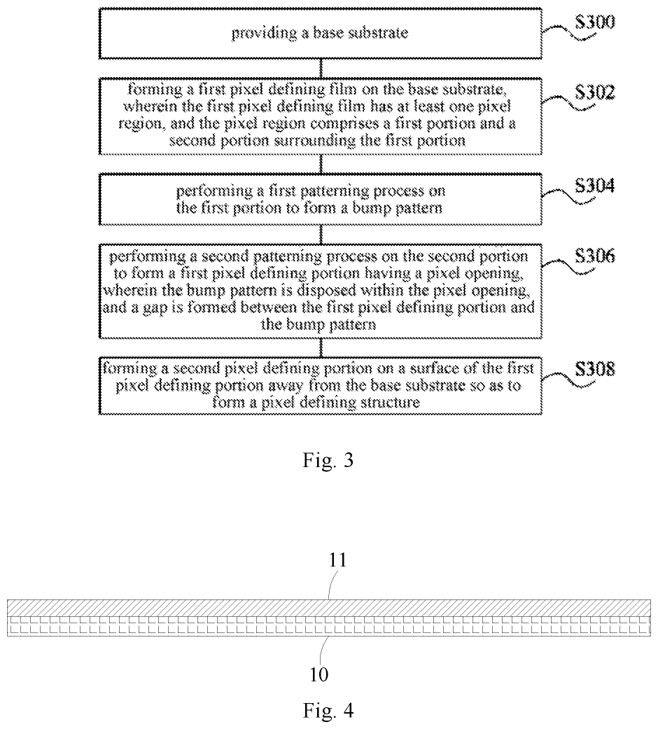

An arrangement of the present disclosure further provides a fabricating method of a pixel defining structure used to fabricate the pixel defining structure described in any one of the arrangements. As shown in FIG. 3, the fabricating method of the pixel defining structure may include the following blocks:

Block S300: providing a base substrate;

Block S302: forming a first pixel defining film on the base substrate. The first pixel defining film has at least one pixel region, and the pixel region includes a first portion and a second portion surrounding the first portion;

Block S304: performing a first patterning process on the first portion to form a bump pattern;

Block S306: performing a second patterning process on the second portion to form a first pixel defining portion having a pixel opening. The bump pattern is disposed within the pixel opening, and a gap is formed between the first pixel defining portion and the bump pattern; and

Block S308: forming a second pixel defining portion on a surface of the first pixel defining portion away from the base substrate so as to form a pixel defining structure.

In this arrangement, by providing the convex pattern in the pixel opening of the first pixel defining portion, the surface tension of the organic light emitting solution filled in the pixel opening can be damaged, so that the situation that the organic light emitting solution gathers towards the middle under the action of the surface tension of the liquid can be alleviated, i.e., under the action of the convex pattern, the amount of the organic light emitting solution flowing towards the edge (the position where the first pixel defining portion is located) in the pixel opening can be increased, so that the situation that the formed organic light emitting functional layer is thick in the middle and thin in the edge can be alleviated. Thus, the film thickness uniformity of the organic light emitting functional layer in the pixel opening is improved, the situation that the coffee ring effect occurs is alleviated, and then the light emitting effect is improved.

It should be noted that S304 and S306 may be performed simultaneously; S304 may be firstly performed before performing S306.

The following describes a fabricating method of the pixel defining structure of the present arrangement in detail with reference to the drawings.

As shown in FIGS. 4 to 7, in block S300, a base substrate 10 is provided. The base substrate 10 may have a multi-layer structure, but is not limited thereto, and may have a single-layer structure. For example, the base substrate 10 may be applied to a display panel, and the base substrate 10 may include functional layers such as a pixel driving circuit.

As shown in FIG. 4, in block S302, a first pixel defining film 11 having at least one pixel region is formed on a base substrate 10, and the pixel region includes a first portion and a second portion surrounding the first portion. For example, the first pixel defining film 11 may be coated on the base substrate 10 by using a coater and then cured, but not limited thereto, a layer of the first pixel defining film 11 may be deposited on the base substrate 10 by using a magnetron sputtering method, a thermal evaporation method, or a PECVD (Plasma Enhanced Chemical Vapor Deposition) method. The first pixel defining film 11 may be made of lyophilic material. And the thickness of the first pixel defining film 11 may be 1.0 μm to 2.0 μm, but is not limited thereto, and the thickness of the first pixel defining film 11 may be set according to actual needs.

It should be noted that, when the base substrate 10 includes functional layers such as a pixel driving circuit, an anode layer may be formed between the first pixel defining film 11 and the base substrate 10, the anode layer may be connected to the pixel driving circuit layer, and a part of the first pixel defining film 11 corresponding to the anode layer may be a pixel region.

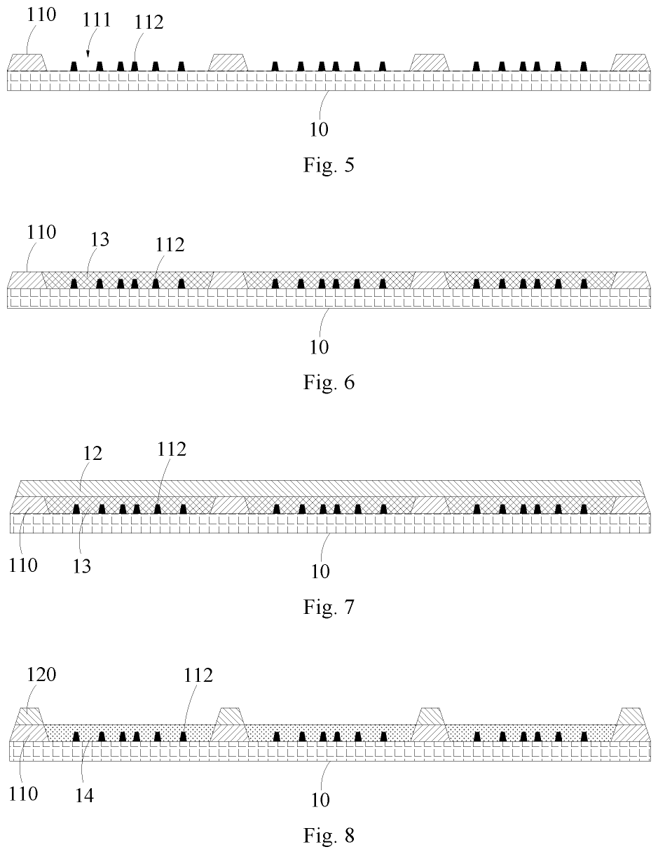

As shown in FIG. 5, in block S304, a first patterning process is performed on the first portion of the pixel region to form a bump pattern.

In one arrangement, the block S304 may include S3040, S3042, S3044 and S3046.

In S3040, a photoresist layer is formed on the first pixel defining film 11. For example, a photoresist material may be coated on the first pixel defining film 11 by spin coating or the like to form a photoresist layer.

In S3042, the photoresist layer is exposed and developed to form a photoresist pattern covering the first portion. For example, a preset mask plate may be used to expose the photoresist layer, and then a developing operation may be performed on the exposed photoresist layer. When the photoresist layer is made of positive photoresist material, the photosensitive region of the photoresist layer may be dissolved in developing solution; or when the photoresist layer is made of negative photoresist material, the non-photosensitive region of the photoresist layer may be dissolved in the developing solution, so that the photoresist pattern is exposed.

In S3044, a dry etching process is performed on the first portion by using the photoresist pattern as a photolithography mask to form the bump pattern. For example, it is mentioned that the bump pattern may include a plurality of bumps 112 spaced apart, and the thickness of each bump 112 may be controlled by controlling the dry etching rate and time when the dry etching process is performed. The thickness of the bump 112 may be 0.5 μm to 1.0 μm, but is not limited thereto. It should be noted that the foregoing arrangements have already described the structure of the bump pattern in detail, and therefore, the detailed description will not be repeated here.

In S3046, the photoresist pattern is removed to complete the entire process of forming the bump pattern. For example, the photoresist pattern may be stripped from the bump pattern by using a stripping solution, but is not limited thereto. Note that the stripping solution is used only for stripping the photoresist pattern, and does not affect the bump pattern and other portions on the first pixel defining film 11.

In another arrangement, the first pixel defining film 11 may be made of photolithographic organic material, and thus, the block S304 may include: exposing and developing the first portion of the pixel region to form the bump pattern. For example, a preset mask plate may be used to expose a first portion of the pixel region, and then a developing operation may be performed on the exposed first portion. When the photo-etching organic material is a positive photoresist material, the photosensitive region of the first portion may be dissolved in a developing solution, or when the photo-etching organic material is a negative photoresist material, the non-photosensitive region of the first portion may be dissolved in a developing solution, so that the bump pattern is exposed.

As shown in FIG. 5, in block S306, a second patterning process is performed on the second portion to form a first pixel defining portion 110 having a pixel opening 111. The pixel opening 111 has a bump pattern therein, and a gap is formed between the first pixel defining portion 110 and the bump pattern. For example, the second portion may be subjected to an operation such as gluing, exposing, developing, etc., to form the first pixel defining portion 110.

In block S308, a second pixel defining portion 120 is formed on the surface of the first pixel defining portion 110 away from the base substrate 10 to form a pixel defining structure. For example, the block S308 may include

S3080: forming a protection layer 13 covering the bump pattern in the pixel opening 111. As shown in FIG. 6, the protection layer 13 may be a photoresist;

S3082: forming a second pixel defining film 12 covering the first pixel defining portion 110 and the protection layer 13, as shown in FIG. 7. The second pixel defining film 12 can be made of lyophobic material; and the second pixel defining film 12 may be coated on the first pixel defining portion 110 and the protective layer 13 by using a coater and then cured, but is not limited thereto, and may be deposited on the first pixel defining portion 110 and the protective layer 13 by using a magnetron sputtering, a thermal evaporation, or a PECVD method. The thickness of the second pixel defining film 12 may be set according to actual needs.

S3084: the second pixel defining film 12 is wet-etched with an etching solution to remove part of the second pixel defining film 12 corresponding to the pixel opening 111 and the protection layer 13, so as to obtain the second pixel defining portion 120 formed on the surface of the first pixel defining portion 110 away from the base substrate 10. In other words, other portions of the second pixel defining film 12 except the portion opposite to the surface of the first pixel defining portion 110 away from the base substrate 10 can be removed by the etching solution, so as to form the second pixel defining portion 120 on the surface of the first pixel defining portion 110 away from the base substrate 10, as shown in FIG. 1, thus completing the fabrication of the entire pixel defining structure.

Note that the etching liquid does not affect the bump 112 and the first pixel defining portion 110.

In an arrangement, since it is mentioned that the first pixel defining portion 110 may be made of lyophilic material and the second pixel defining portion 120 may be made of lyophobic material, so that, in order to ensure the bonding stability of the first pixel defining portion 110 and the second pixel defining portion 120, after S306 and before S308, the surface of the first pixel defining portion 110 away from the base substrate 10 may be modified to make the surface of the first pixel defining portion 110 away from the base substrate 10 compatible with the second pixel defining portion 120.

For example, after S3080 and before S3082, the surface of the first pixel defining portion 110 away from the base substrate 10 may be modified, so that the influence on the performance of the side surface of the first pixel defining portion 110, the base substrate 10 and the bump pattern during the modification process may be avoided, and the film formation uniformity of the subsequent organic light emitting functional layer 14 may be ensured.

An arrangement of the present disclosure also provides a display panel which may be an OLED display panel, but is not limited thereto, for example, it may also be a QLED display panel. As shown in FIG. 8, the display panel may include a base substrate 10, a pixel defining structure formed on the base substrate 10, and an organic light emitting functional layer 14 formed in a pixel opening 111 defined by the pixel defining structure. The pixel defining structure may be the pixel defining structure described in any of the above arrangements, and details thereof will not be repeated herein.

In practice, the display panel may further include at least an anode layer (not shown) disposed between the base substrate 10 and the pixel defining structure, and a cathode layer (not shown) disposed on the organic light emitting functional layer 14.

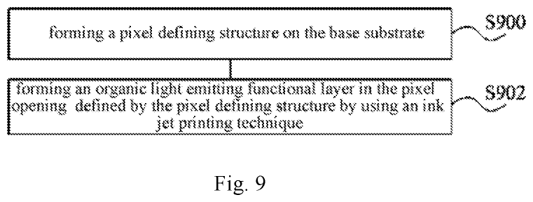

An arrangement of the present disclosure further provides a fabricating method of a display panel, as shown in FIG. 9, the fabricating method of the display panel may include the following blocks.

Block S900: forming a pixel defining structure on the base substrate 10; specifically, the pixel defining structure may be formed on the base substrate 10 by using the fabricating method of the pixel defining structure described in any one of the foregoing arrangements;

Block S902: forming an organic light emitting functional layer 14 in the pixel opening 111 defined by the pixel defining structure by using an ink jet printing technique, as shown in FIG. 8; specifically, the organic light emitting functional layer 14 made of the organic electroluminescent material can be obtained by spraying a solution containing the organic electroluminescent material into the pixel opening 111 and then baking the solution. It should be noted that the pixel defining structure described in this arrangement can also be applied to an inorganic electroluminescent material (e.g., a quantum dot light emitting material), a photo-luminescent material, or other auxiliary light emitting materials, and is not limited herein.

An arrangement of the present disclosure further provides a display device, which may include the display panel described in the foregoing arrangements, and the display device may be any product or component with a display function, such as electronic paper, a mobile phone, a tablet computer, a television, a display, a notebook computer, a digital photo frame, and a navigator.

Other arrangements of the present disclosure will be apparent to those skilled in the art after reading the specification and implementing the present disclosure disclosed herein. The present application is intended to cover any variations, purposes, or adaptations of the present disclosure, which are in accordance with the general principles of the present disclosure and include common general knowledge or conventional technical means in the art that are not disclosed in the present disclosure. The specification and arrangements are to be regarded as illustrative only, and the real scope and spirit of the present disclosure is defined by the attached claims.

What is claimed is:

1. A pixel defining structure comprising:
a first pixel defining portion on a base substrate, the first pixel defining portion having a pixel opening;
a bump pattern on the base substrate and located in the pixel opening, a gap being formed between the bump pattern and the first pixel defining portion; and
a second pixel defining portion on a surface of the first pixel defining portion away from the base substrate.

2. The pixel defining structure according to claim 1, wherein the bump pattern is mirror-symmetrical with respect to a center line of the pixel opening.

3. The pixel defining structure according to claim 1, wherein the bump pattern comprises a plurality of bumps spaced apart from one another, and a distance between adjacent bumps gradually increases along a direction from a center of the bump pattern to an edge of the bump pattern.

4. The pixel defining structure according to claim 3, wherein a thickness of each of the bumps is less than a thickness of the first pixel defining portion.

5. The pixel defining structure according to claim 4, wherein each of the bumps has a thickness of about 0.5 μm to about 1.0 μm, and the first pixel defining portion has a thickness of about 1.0 μm to about 2.0 μm.

6. The pixel defining structure according to claim 1, wherein the first pixel defining portion and the bump pattern are made of a lyophilic material, and the second pixel defining portion is made of a lyophobic material.

7. The pixel defining structure according to claim 1, wherein an orthographic projection of a surface of the first pixel defining portion away from the base substrate on the base substrate is within an orthographic projection of a surface of the first pixel defining portion adjacent to the base substrate on the base substrate.

8. The pixel defining structure according to claim 2, wherein an orthographic projection of a surface of the first pixel defining portion away from the base substrate on the base substrate is within an orthographic projection of a surface of the first pixel defining portion adjacent to the base substrate on the base substrate.

9. The pixel defining structure according to claim 3, wherein an orthographic projection of a surface of the first pixel defining portion away from the base substrate on the base substrate is within an orthographic projection of a surface of the first pixel defining portion adjacent to the base substrate on the base substrate.

10. The pixel defining structure according to claim 1, wherein an orthographic projection of a surface of the second pixel defining portion away from the base substrate on the base substrate is within an orthographic projection of a surface of the second pixel defining portion adjacent to the base substrate on the base substrate.

11. The pixel defining structure according to claim 2, wherein an orthographic projection of a surface of the second pixel defining portion away from the base substrate on the base substrate is within an orthographic projection of a surface of the second pixel defining portion adjacent to the base substrate on the base substrate.

12. The pixel defining structure according to claim 3, wherein an orthographic projection of a surface of the second pixel defining portion away from the base substrate on the base substrate is within an orthographic projection of a surface of the second pixel defining portion adjacent to the base substrate on the base substrate.

13. The pixel defining structure according to claim 1, wherein an orthographic projection area of a surface of the second pixel defining portion adjacent to the base substrate on the base substrate is equal to an orthographic projection area of a surface of the first pixel defining portion away from the base substrate on the base substrate.

14. The pixel defining structure according to claim 2, wherein an orthographic projection area of a surface of the second pixel defining portion adjacent to the base substrate on the base substrate is equal to an orthographic projection area of a surface of the first pixel defining portion away from the base substrate on the base substrate.

15. A fabricating method of a pixel defining structure comprising:
providing a base substrate;
forming a first pixel defining film on the base substrate, wherein the first pixel defining film has at least one pixel region, and the pixel region comprises a first portion and a second portion surrounding the first portion;
performing a first patterning process on the first portion to form a bump pattern;
performing a second patterning process on the second portion to form a first pixel defining portion having a pixel opening, wherein the bump pattern is disposed within the pixel opening, and a gap is formed between the first pixel defining portion and the bump pattern; and
forming a second pixel defining portion on a surface of the first pixel defining portion away from the base substrate so as to form a pixel defining structure.

16. The fabricating method according to claim 15, wherein performing the first patterning process on the first portion to form the bump pattern comprising:
forming a photoresist layer on the first pixel defining film;
exposing and developing the photoresist layer to form a photoresist pattern covering the first portion;
performing a dry etching process on the first portion by taking the photoresist pattern as a mask to form the bump pattern; and
removing the photoresist pattern.

17. The fabricating method according to claim 15, wherein
the first pixel defining film is made by means of photo-etching an organic material; and
performing the first patterning process on the first portion to form the bump pattern comprises:
exposing and developing the first portion to form the bump pattern.

18. The fabricating method according to claim 15, wherein
the first pixel defining portion is made of lyophilic material, and the second pixel defining portion is made of lyophobic material; and
after performing the second patterning process on the second portion to form the first pixel defining portion having the pixel opening, and before forming the second pixel defining portion on the surface of the first pixel defining portion away from the base substrate, the fabricating method further comprises:
improving the surface of the first pixel defining portion away from the base substrate so as to enable the surface of the first pixel defining portion away from the base substrate to be compatible with the second pixel defining portion.

19. A display panel comprising:
a base substrate;
a pixel defining structure on the base substrate, the pixel defining structure being a pixel defining structure according to claim 1; and
an organic light emitting functional layer in a pixel opening defined by the pixel defining structure.

20. A display device comprising a display panel according to claim 19.
